(19) United States
(12) Patent Application Publication
(10) Pub. No.: US 2012/0007042 A1
(43) Pub. Date: Jan. 12, 2012

(54) LIGHT EMITTING DEVICE WITH A SINGLE QUANTUM WELL ROD

(75) Inventors: Min-Hsun HSIEH, Hsinchu (TW); Hung-Chih YANG, Hsinchu (TW); Ta-Cheng HSU, Hsinchu (TW); Shih-Chang LEE, Hsinchu (TW); Sheng-Horng YEN, Hsinchu (TW); Yung-Hsiang LIN, Hsinchu (TW); Shih-Pang CHANG, Hsinchu (TW)

(73) Assignee: Epistar Corporation, Hsinchu (TW)

(21) Appl. No.: 13/179,030

(22) Filed: Jul. 8, 2011

Related U.S. Application Data
(60) Provisional application No. 61/363,078, filed on Jul. 9, 2010.

(51) Int. Cl. H01L 33/04; H01L 33/50

(52) U.S. Cl. 257/13; 438/22; 257/E33.008; 257/E33.019

(57) ABSTRACT

A light emitting device comprising a first semiconductor layer, a second semiconductor layer and a quantum well layer, wherein the first semiconductor layer and the second semiconductor layer are disposed on the opposite sides of the quantum well layer, the quantum well layer comprising a plurality of quantum well rods which are separated from each other, and each of the quantum well rods has only one quantum well.

### BACKGROUND

1. Technical Field

The application relates to a light emitting device with a single quantum well rod and the manufacturing method thereof.

2. Related Application Data

The features of LED mainly include small size, high efficiency, long life, quick reaction, high reliability, and fine color. So far, LED has been applied to electronic devices, vehicles, signboards, and traffic signs. Along with the launch of the full-color LED, LED has gradually replaced traditional lighting apparatus such as fluorescent lights and incandescent lamps.

There are several important factors to influence the light-emitting efficiency of LED, and the external quantum efficiency (EQE) is one of them. EQE is defined as the ratio of the number of photons generated by the active region of the light-emitting diode and the number of electrons injected into the active area per unit time. In the ideal case, each electron injected into the active region should be combined with a hole to generate a photon. However, in the actual operation, the LED can hardly achieve this result. In a worse situation, when the operating current is increased to produce more light, the external quantum efficiency is decreased, which is also known as the external quantum efficiency droop (EQE droop), that limits the performance of light-emitting diodes at high current operation. Therefore, the EQE droop effect needs to be solved.

### SUMMARY

The present disclosure provides a novel structure and the manufacturing method thereof for increasing the light extraction efficiency.

One aspect of the present disclosure provides an light emitting device comprising: a first semiconductor layer of first conductivity-type; a second semiconductor layer of second conductivity-type; a quantum well layer, wherein the first semiconductor layer and the second semiconductor layer are disposed on the opposite sides of the quantum well layer, the quantum well layer comprising a plurality of quantum well rods which are separated from each other, and each of the quantum well rod has only one quantum well.

### BRIEF DESCRIPTION OF THE DRAWINGS

FIGS. 1A to 1E illustrate the corresponding structures fabricated by the manufacturing method step-by-step according to one embodiment of the present disclosure.

FIG. 1F illustrates quantum well rods according to one embodiment of the present disclosure.

FIG. 2 illustrates a light emitting device in accordance with the present disclosure with an x-axis direction.

FIGS. 3A-3E illustrate the corresponding structures fabricated by the manufacturing method step-by-step according to one embodiment of the present disclosure.

FIG. 4 illustrates a light emitting device with a wavelength conversion material according to one embodiment of the present disclosure.

### DETAILED DESCRIPTION OF PREFERRED EMBODIMENTS

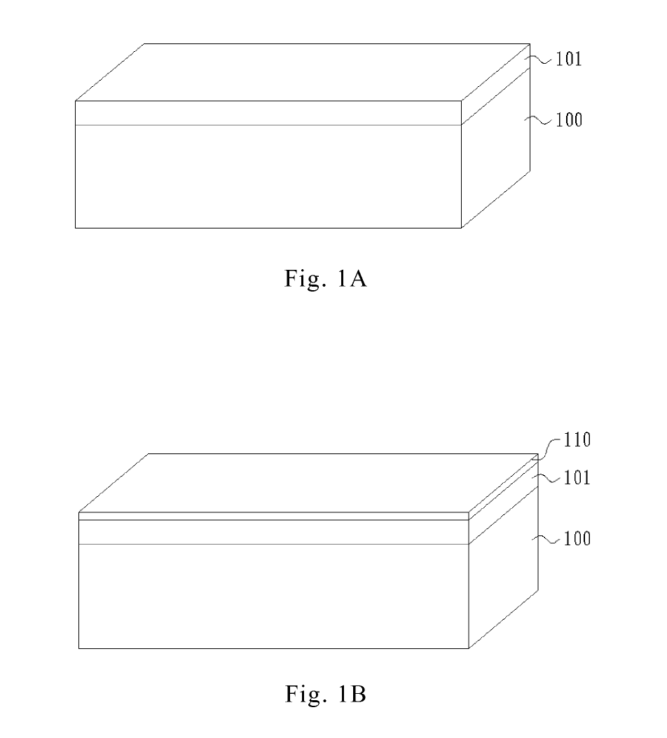

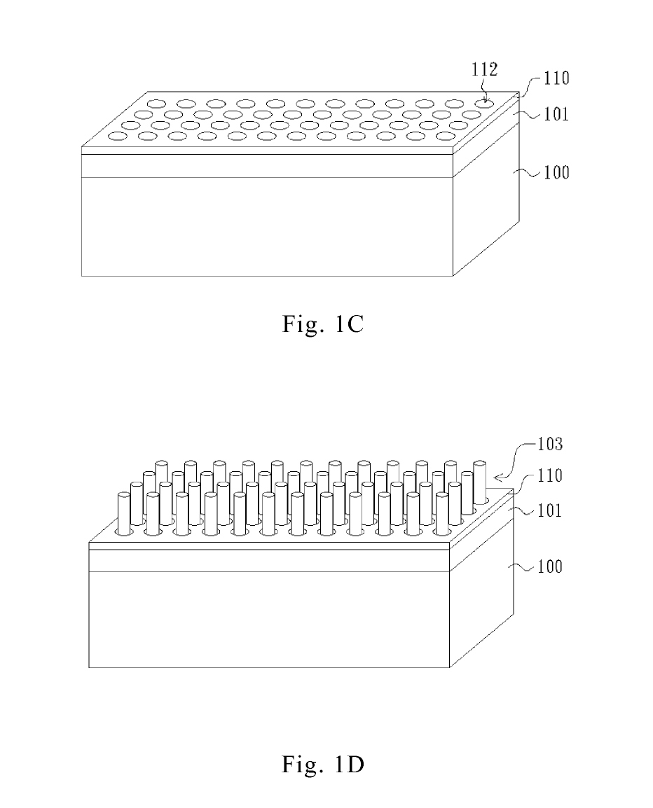

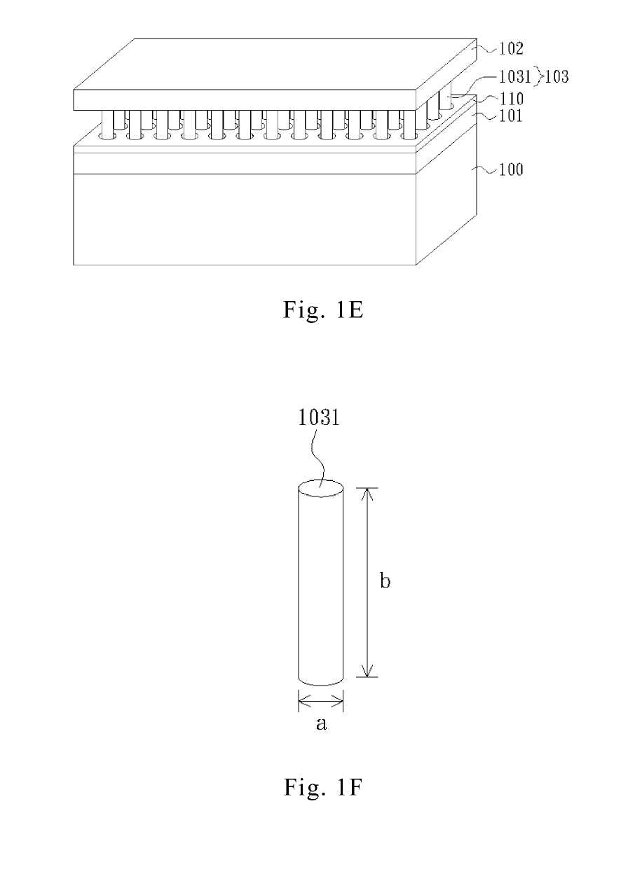

The disclosure discloses a light-emitting diode structure with a single quantum well rod and its manufacturing method. FIG. 1 shows a manufacturing process of the first embodiment. In FIG. 1A, a first semiconductor layer 101 is formed on a substrate 100 by epitaxial growth. Then, as shown in FIG. 1B, a dielectric layer 110 is formed on the first semiconductor layer 101. FIG. 1C shows that the dielectric layer 110 is etched to form a plurality of holes 112 by lithography and etching techniques. Then, as shown in FIG. 1D, using the MOCVD process to form a quantum well layer 103 through holes 112. As shown in FIG. 1E, a second semiconductor layer 102 is formed on the top of the quantum well layer 103. The quantum well layer 103 includes a plurality of the quantum well rods 1031, wherein each quantum well rod 1031 has a single quantum well. As shown in FIG. 1F, a quantum well rod 1031 with a maximum width a (for example, if the quantum well rod is cylinder, the maximum width is the diameter of its circular cross-section) and a height b. The quantum well rod 1031 with only one single quantum well has no potential energy barrier to block the charged carriers. Therefore, electrons and holes can be evenly distributed in the quantum well rod 1031, and the recombination efficiency is increased and thus the EQE droop is relieved.

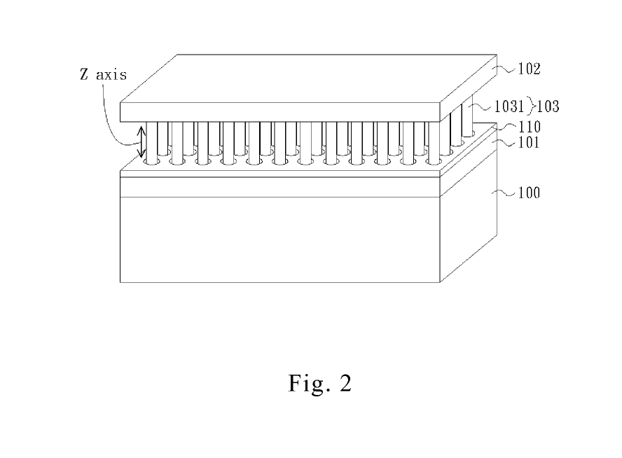

The disclosure discloses another embodiment of the present application. In addition to the above mentioned description, the maximum width a of the quantum well rods 1031 is less than or equal to 1 μm, and better to be less than or equal to 500 nm. The height b of the quantum well rods 1031 is greater than or equal to 50 nm, and better to be greater than or equal to 100 nm. Thus, in addition to improve the hole injection efficiency with the quantum well having no potential energy barrier, the geometry characteristics of quantum well rods 1031 also limit the movement of charged carriers (electrons and holes) along the axis (growth direction) of quantum well rods. When the first semiconductor layer 101 and the second semiconductor layer 102 has a voltage difference between them, the first semiconductor layer 101 and the second semiconductor layer generates a flow of electrons and holes between them. The electrons and holes flow in opposite directions to each other, for example, when the electron flows from the first semiconductor layer 101 to the second semiconductor layer 102, the hole flows from the second semiconductor layer 102 to the first semiconductor layer 101. The recombination of electrons and holes 102 in the rod generate photons. Because the geometry limitation of the quantum well rod 1031, electrons and holes without potential energy barrier are restrained to the Z-axis (growth direction), as shown in FIG. 2. Therefore, the recombination efficiency of electrons and holes is greatly improved, thereby increasing the EQE.

The material of the first semiconductor layer 101 and the second semiconductor layer 102 includes III-nitride compounds which includes but is not limited to aluminum gallium indium nitride (AlGaInN) series material, such as aluminum gallium nitride (AlGaN), gallium nitride (GaN) or indium gallium nitride (GaInN); aluminum gallium arsenide (AlGaAs) series material, such as arsenic gallium (GaAs), indium gallium aluminum phosphide; or (AlGaInP) series of materials such as gallium aluminum phosphide (AlGaP) or gallium phosphide (GaP). The material of quantum well rods 1031 includes III-nitride compounds which includes but is not limited to InGaN , GaN, AlGaInN, AlGaN, GaN), or GaInN. In another embodiment, the material is aluminum gallium arsenide (AlGaAs) series material, such as gallium arsenide (GaAs).

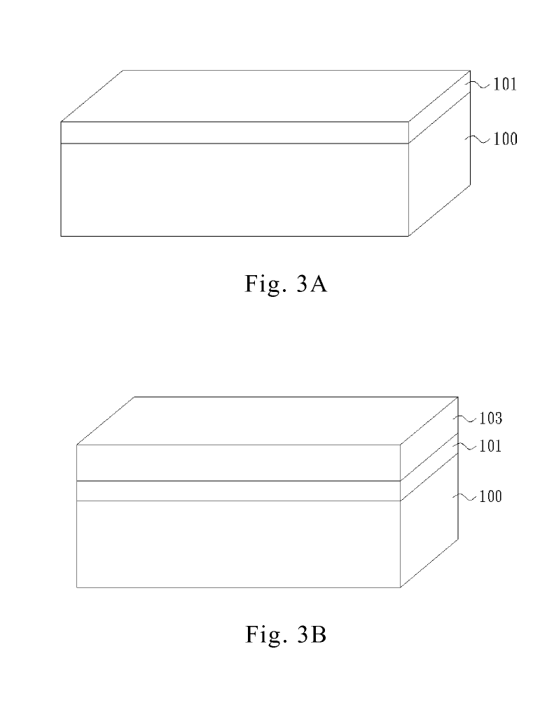

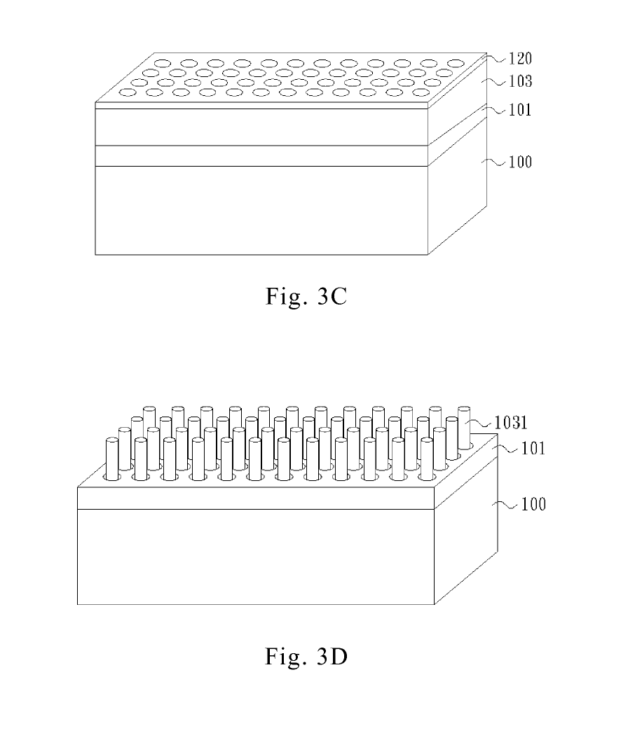

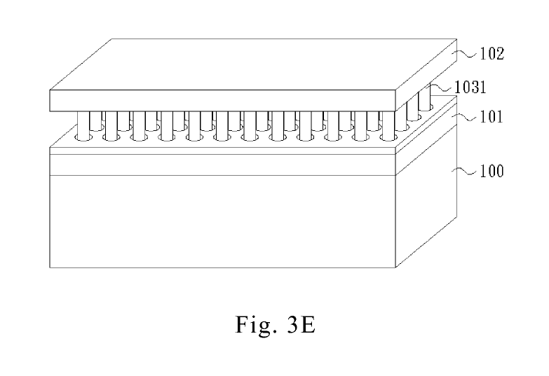

FIG. 3 represents a manufacturing process of another embodiment. In FIG. 3A, a substrate 100 is provided. Then forming a first semiconductor layer 101 above the substrate 100 by epitaxial growth. Then, as shown in FIG. 3B, forming a quantum well layer 103 on the first semiconductor flayer 101. As shown in FIG. 3C, forming a mask layer 120 above the quantum well layer 103 by lithography technology, followed by etching technology to form a plurality of quantum well rods 1031 as shown in FIG. 3D. Then, as shown in FIG. 3E, forming a second semiconductor layer 102 on the quantum well layer 103 by MOCVD, MVPE, and so on. In this embodiment, the maximum width of quantum well rods 1031 may be less than or equal to 1 μm, or less than or equal to 500 nm. In this embodiment, the height b of quantum well rod 1031 can be greater than or equal to 50 nm, or greater than or equal to 100 nm.

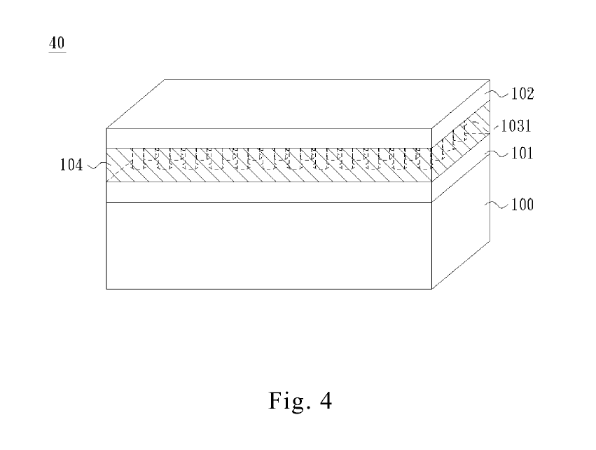

FIG. 4 represents another embodiment of the disclosure. A light-emitting diode 40 includes a first semiconductor layer 101, a second semiconductor layer 102, and a quantum well layer 103, wherein the quantum well layers 103 includes a plurality of quantum well rods 1031. The quantum well rods 1031 are surrounded by a wavelength conversion material 104. The wavelength conversion material 104 fills the gap between the quantum well rods 1031 by electrophoretic deposition approach. The material of wavelength conversion material 104 can be II-VI group elements which in the form of particles or powder. When the electron and hole are combined in the quantum well rods 1031 and generate a light with first wavelength, the light with first wavelength further excites the wavelength conversion material 104 and converts partial of the light with first wavelength to a light with second wavelength. The light with first and second wavelength generates a mixture of light with third wavelength. The wavelength conversion material 104 can be a blue phosphor, yellow phosphor, green phosphor, or red phosphor. The material of wavelength conversion material 104 includes but is not limited to zinc selenide, zinc cadmium selenide, III-phosphide, III-arsenide, and III-nitride, and the combination thereof.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice. Any modification or decoration for present application is not detached from the spirit and the range of such.

What is claimed is:

1. A light emitting device, comprising:
a first semiconductor layer of first conductivity-type;
a second semiconductor layer of second conductivity-type; and
a quantum well layer, wherein the first semiconductor layer and the second semiconductor layer are disposed on the opposite sides of the quantum well layer, the quantum well layer comprising a plurality of quantum well rods which are separated from each other, and each of the quantum well rods has only one quantum well.

2. The light emitting device claim 1, wherein the height of the quantum well rods is less than or equal to 1 micron.

3. The light emitting device claim 2, wherein the quantum well rods have a diameter, wherein a ratio of the height and the diameter is larger than or equal to 0.1.

4. The light emitting device claim 3, wherein the material of the quantum well rods is III-nitride based compounds.

5. The light emitting device claim 1, further comprising a plurality of gaps between the quantum well rods, and a wavelength conversion material filling between the gaps.

6. The light emitting device claim 1, wherein the wavelength conversion material is in the form of particle or powder composed of II-VI semiconductor compounds.

7. A manufacturing method for a light emitting device, comprising the steps of:
forming a first semiconductor layer on a substrate,
forming a dielectric layer on the first semiconductor layer;
forming a plurality of holes in the dielectric layer, wherein the holes penetrate through the dielectric layer;
forming a plurality of quantum well rods in the holes; and
forming a second semiconductor layer above the quantum well rods.

8. A manufacturing method for a light emitting device, comprising the steps of:
forming a first semiconductor layer on a substrate;
forming a quantum well layer on the first semiconductor layer;
etching the quantum well layer to form a plurality of quantum well rods; and
forming a second semiconductor layer on the quantum well rods.

9. The manufacturing method for a light emitting device according to claim 7, further comprising a step of filling a wavelength conversion material between the quantum well rods.

10. The manufacturing method for a light emitting device accordance to claim 8, further comprising a step of filling a wavelength conversion material between the quantum well rods.

11. The manufacturing method for a light emitting device according to claim 10, wherein the wavelength conversion is forming by electrophoresis.
